(19) United States
(12) Patent Application Publication
(10) Pub. No.: US 2026/0136878 A1
(43) Pub. Date: May 14, 2026

(54) METHOD OF ADJUSTING SUBSTRATE TRANSFER POSITION, SUBSTRATE TRANSFER METHOD, AND SUBSTRATE PROCESSING SYSTEM

(71) Applicant: Tokyo Electron Limited, Tokyo (JP)

(72) Inventors: Junichi IWANO, Kumamoto (JP); Akihiro TERAMOTO, Kumamoto (JP); Hiroshi YOSHIDA, Kumamoto (JP); Daisuke MORI, Kumamoto (JP)

(21) Appl. No.: 19/369,799

(22) Filed: Oct. 27, 2025

(30) Foreign Application Priority Data
Nov. 8, 2024 (JP) 2024-195962

(51) Int. Cl. H01L 21/67; H01L 21/677; H01L 21/687

(52) U.S. Cl. CPC H10P 72/0606; H10P 72/0404; H10P 72/3302; H10P 72/3308; H10P 72/7602

(57) ABSTRACT

A method of adjusting a substrate transfer position is provided in a substrate processing system including: a batch processing section; a single-substrate processing section; and a substrate standby section configured to cause a substrate to be transferred from the batch processing section to the single-substrate processing section to wait. The substrate standby section includes: a delivery table; and a first transfer robot including a first holding section. The single-substrate processing section includes a second transfer robot including a second holding section. The method includes: acquiring, by the second holding section, the substrate from the delivery table; detecting a shift amount of the substrate with respect to a reference position while the second holding section holds the substrate acquired from the delivery table; and correcting a horizontal position when the first holding section mounts the substrate on the delivery table, based on the detected shift amount.

### CROSS-REFERENCE TO RELATED APPLICATIONS

This patent application is based on and claims priority to Japanese Patent Application No. 2024-195962 filed on November 8, 2024, the entire contents of which are incorporated herein by reference.

### TECHNICAL FIELD

The present disclosure relates to a method of adjusting a substrate transfer position, a substrate transfer method, and a substrate processing system.

### BACKGROUND

Patent Document 1 discloses a technique of detecting a position of a peripheral portion of a substrate held by a fork with a sensor when the fork is retracted while holding the substrate, and correcting a position where a processing section delivers the substrate to a next processing section, based on a detected value of the sensor.

### Related Art Document

### Patent Document

[Patent Document 1] Japanese Laid-open Patent Application Publication No. 2012-64918

### SUMMARY

According to one aspect of the present disclosure, a method of adjusting a substrate transfer position is provided in a substrate processing system including: a batch processing section configured to collectively process a plurality of substrates; a single-substrate processing section configured to process the plurality of substrates one by one; and a substrate standby section configured to cause a substrate to be transferred from the batch processing section to the single-substrate processing section to wait. The substrate standby section includes: a delivery table on which the substrate is to be mounted; and a first transfer robot configured to mount, on the delivery table, the substrate processed by the batch processing section. The single-substrate processing section includes a second transfer robot configured to acquire the substrate from the delivery table. The first transfer robot includes a first holding section configured to hold the substrate. The second transfer robot includes a second holding section configured to hold the substrate. The method includes: acquiring, by the second holding section, the substrate from the delivery table; detecting a shift amount of the substrate with respect to a reference position while the second holding section holds the substrate acquired from the delivery table; and correcting a horizontal position when the first holding section mounts the substrate on the delivery table, based on the detected shift amount.

### BRIEF DESCRIPTION OF THE DRAWINGS

FIG. 1 is a schematic plan view illustrating an example of a substrate processing system;

FIG. 2 is a view illustrating an example of a second delivery section;

FIG. 3 is a flowchart illustrating an example of a substrate processing method;

FIG. 4 is a view illustrating an example of a method of adjusting a substrate transfer position;

FIG. 5 is a view illustrating an example of the method of adjusting the substrate transfer position;

FIG. 6 is a view illustrating an example of the method of adjusting the substrate transfer position;

FIG. 7 is a view illustrating an example of the method of adjusting the substrate transfer position;

FIG. 8 is a view illustrating an example of the method of adjusting the substrate transfer position;

FIG. 9 is a view illustrating an example of the method of adjusting the substrate transfer position;

FIG. 10 is a view illustrating an example of the method of adjusting the substrate transfer position;

FIG. 11 is a view illustrating an example of the method of adjusting the substrate transfer position;

FIG. 12 is a view illustrating an example of the method of adjusting the substrate transfer position;

FIG. 13 is a view illustrating an example of the method of adjusting the substrate transfer position;

FIG. 14 is a view illustrating an example of the method of adjusting the substrate transfer position;

FIG. 15 is a view illustrating an example of the method of adjusting the substrate transfer position;

FIG. 16 is a view illustrating an example of the method of adjusting the substrate transfer position;

FIG. 17 is a view illustrating an example of the method of adjusting the substrate transfer position;

FIG. 18 is a view illustrating an example of the method of adjusting the substrate transfer position;

FIG. 19 is a view illustrating an example of the method of adjusting the substrate transfer position;

FIG. 20 is a view illustrating an example of the method of adjusting the substrate transfer position;

FIG. 21 is a view illustrating an example of the method of adjusting the substrate transfer position;

FIG. 22 is a view illustrating an example of the method of adjusting the substrate transfer position;

FIG. 23 is a view illustrating an example of the method of adjusting the substrate transfer position;

FIG. 24 is a view illustrating an example of the method of adjusting the substrate transfer position;

FIG. 25 is a view illustrating an example of the method of adjusting the substrate transfer position;

FIG. 26 is a view illustrating another example of the method of adjusting the substrate transfer position;

FIG. 27 is a view illustrating another example of the method of adjusting the substrate transfer position;

FIG. 28 is a view illustrating another example of the method of adjusting the substrate transfer position;

FIG. 29 is a view illustrating another example of the method of adjusting the substrate transfer position;

FIG. 30 is a view illustrating another example of the method of adjusting the substrate transfer position; and

FIG. 31 is a view illustrating another example of the method of adjusting the substrate transfer position.

### DETAILED DESCRIPTION

Hereinafter, non-limiting exemplary embodiments of the present disclosure will be described with reference to the accompanying drawings. In all the attached drawings, the same or corresponding members or parts are denoted by the same or corresponding reference numerals, and duplicate descriptions are omitted.

In the following description, the XYZ Cartesian coordinate system is used, but the coordinate system is specified for the purpose of explanation and does not limit the orientation of a substrate processing system 1. The XY plane view is referred to as the plan view, and from an arbitrary point, the positive side of the Z-axis may be referred to as “above”, and the negative side of the Z-axis may be referred to as “below”.

### Substrate Processing System

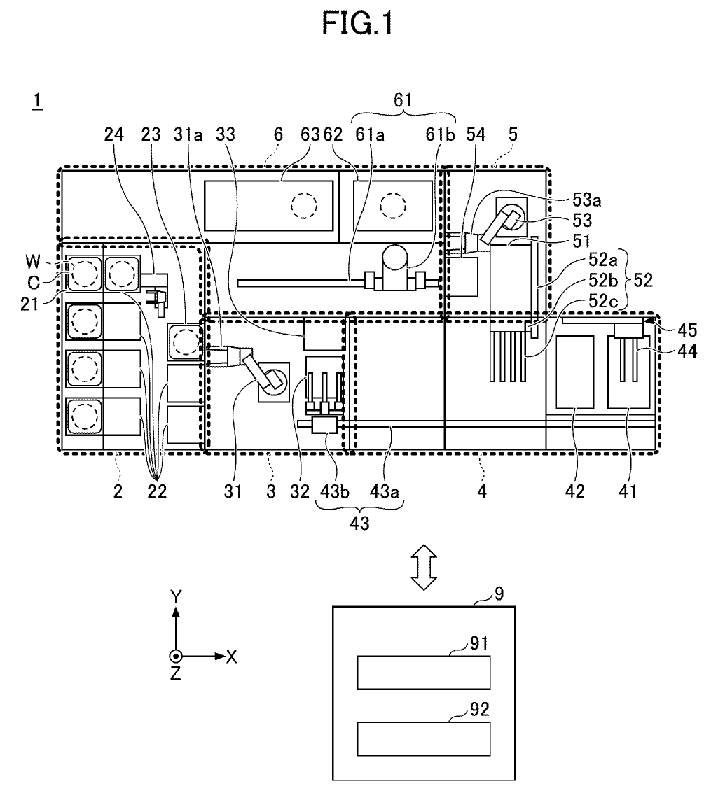

A substrate processing system 1 according to an embodiment will be described with reference to FIG. 1. FIG. 1 is a schematic plan view illustrating an example of the substrate processing system 1.

As illustrated in FIG. 1, the substrate processing system 1 includes a carry-in/out section 2, a first interface section 3, a batch processing section 4, a second interface section 5, a single-substrate processing section 6, and a control circuit 9.

The carry-in/out section 2 serves as both a carry-in section and a carry-out section. Thus, the substrate processing system 1 can be miniaturized. The carry-in/out section 2 includes a load port 21, a stocker 22, a loader 23, and a cassette transfer device 24.

The load port 21 is disposed on the negative side of the X-axis in the carry-in/out section 2. A plurality of (for example, four) load ports 21 are disposed along the Y-axis. The number of load ports 21 is not particularly limited. A cassette C is mounted on the load port 21. The cassette C accommodates a plurality of (for example, 25) substrates W. The cassette C is transferred to and from the load port 21. Inside the cassette C, the substrates W are held horizontally and held at a second pitch P2 (P2=N×P1), which is N times a first pitch P1 along the Z-axis. N is a natural number greater than or equal to two. In the present embodiment, N is two, but may be three or greater.

A plurality of (for example, four) stockers 22 are disposed along the Y-axis at the center of the carry-in/out section 2 in the X-axis. A plurality of (for example, two) stockers 22 are disposed along the Y-axis adjacent to the first interface section 3 on the positive side of the X-axis in the carry-in/out section 2. The stockers 22 may be disposed in multiple stages along the Z-axis. The stockers 22 temporarily store the cassette C in which the substrates W before cleaning processing are stored, the cassette C from which the substrates W are taken out and the inside is empty, and the like. The number of stockers 22 is not particularly limited.

The loader 23 is adjacent to the first interface section 3. The loader 23 is disposed on the positive side of the X-axis in the carry-in/out section 2. The cassette C is mounted on the loader 23. The loader 23 is provided with a cover opening/closing mechanism (which is not illustrated) for opening and closing a cover of the cassette C. A plurality of loaders 23 may be provided. The loaders 23 may be disposed in multiple stages along the Z-axis.

The cassette transfer device 24 transfers the cassette C between the load port 21, the stocker 22, and the loader 23. The cassette transfer device 24 is, for example, an articulated transfer robot.

The first interface section 3 is disposed on the positive X-axis side of the carry-in/out section 2. The first interface section 3 transfers the substrate W between the carry-in/out section 2, the batch processing section 4, and the single-substrate processing section 6. The first interface section 3 includes a substrate transfer device 31, a lot formation section 32, and a first delivery section 33.

The substrate transfer device 31 transfers the substrate W between the cassette C mounted on the loader 23, the lot formation section 32, and the first delivery section 33. The substrate transfer device 31 includes a multi-axis (for example, six axes) vertically articulated robot, and includes a substrate holding arm 31a at its tip. The substrate holding arm 31a has a plurality of holding claws (which are not illustrated) capable of holding a plurality of (for example, 25) substrates W. The substrate holding arm 31a can take an arbitrary position and orientation in the three-dimensional space while holding the substrate W by the holding claws.

The lot formation section 32 is disposed on the positive side of the X-axis in the first interface section 3. The lot formation section 32 holds a plurality of substrates W at the first pitch P1 (P1 = P2/N) to form a lot L.

The first delivery section 33 is adjacent to the single-substrate processing section 6. The first delivery section 33 is disposed on the positive side of the Y-axis in the first interface section 3. The first delivery section 33 receives the substrate W from a fourth transfer device 61 and temporarily stores the substrate W until the substrate W is delivered to the carry-in/out section 2.

The batch processing section 4 is disposed on the positive X-axis side of the first interface section 3. The carry-in/out section 2, the first interface section 3, and the batch processing section 4 are disposed in this order from the negative side of the X-axis to the positive side of the X-axis. The batch processing section 4 collectively processes the lot L including a plurality of (for example, 50 or 100) substrates W at the first pitch P1. One lot L is composed of, for example, the substrates W of M cassettes C. M is a natural number greater than or equal to two. M may be a natural number equal to or different from N. The batch processing section 4 includes a chemical solution tank 41, a rinse solution tank 42, a first transfer device 43, a treatment tool 44, and a driving device 45.

The chemical solution tank 41 and the rinse solution tank 42 are disposed along the X-axis. For example, from the positive side of the X-axis to the negative side of the X-axis, the chemical solution tank 41 and the rinse solution tank 42 are arranged in this order. The chemical solution tank 41 and the rinse solution tank 42 are together referred to as a processing tank. The number of chemical solution tanks 41 and rinse solution tanks 42 is not limited to that illustrated in FIG. 1. For example, there is one set of the chemical solution tank 41 and the rinse solution tank 42 in FIG. 1, but there may be multiple sets.

The chemical solution tank 41 stores a chemical solution into which the lot L is to be immersed. The chemical solution is, for example, an aqueous phosphoric acid solution (H₃PO₄). The aqueous phosphoric acid solution selectively etches and removes, among a silicon oxide film and a silicon nitride film, the silicon nitride film. The chemical solution is not limited to the aqueous phosphoric acid solution. The chemical solution may be dilute hydrofluoric acid (DHF), buffered hydrofluoric acid (BHF) (the mixture of hydrofluoric acid and ammonium fluoride), dilute sulfuric acid, sulfuric acid-hydrogen peroxide mixture (SPM) (the mixture of sulfuric acid, hydrogen peroxide, and water), Standard Clean 1 (SC1) (the mixture of ammonia, hydrogen peroxide, and water), Standard Clean 2 (SC2) (the mixture of hydrochloric acid, hydrogen peroxide, and water), tetramethylammonium hydroxide (TMAH) (the mixture of tetramethylammonium hydroxide and water), a plating solution, or the like. The chemical solution may be for a stripping or plating process. The number of chemical solutions is not particularly limited and may be plural.

The rinse solution tank 42 stores a first rinse solution into which the lot L is to be immersed. The first rinse solution is pure water for removing the chemical solution from the substrate W, and is, for example, deionized water (DIW).

The first transfer device 43 includes a guide rail 43a and a first transfer arm 43b. The guide rail 43a is disposed on the negative Y-axis side of the processing tank. The guide rail 43a extends along the X-axis from the first interface section 3 to the batch processing section 4. The first transfer arm 43b moves along the guide rail 43a. The first transfer arm 43b may move along the Z-axis or rotate around the Z-axis. The first transfer arm 43b collectively transfers the lot L between the first interface section 3 and the batch processing section 4.

The treatment tool 44 receives and holds the lot L from the first transfer arm 43b. The treatment tool 44 holds the plurality of substrates W at the first pitch P1 along the Y-axis and holds each of the plurality of substrates W vertically.

The driving device 45 moves the treatment tool 44 along the X-axis and the Z-axis. The treatment tool 44 immerses the lot L in the chemical solution stored in the chemical solution tank 41, then immerses the lot L in the first rinse solution stored in the rinse solution tank 42, and subsequently delivers the lot L to the first transfer device 43.

The number of units of the treatment tools 44 and the driving devices 45 is one in the present embodiment, but a plurality of units may be used. In the latter case, one unit immerses the lot L in the chemical solution stored in the chemical solution tank 41, and another unit immerses the lot L in the first rinse solution stored in the rinse solution tank 42. In this case, the driving device 45 only needs to move the treatment tool 44 along the Z-axis, and does not need to move the treatment tool 44 along the X-axis.

The second interface section 5 is disposed on the positive Y-axis side of the batch processing section 4. The second interface section 5 transfers the substrate W between the batch processing section 4 and the single-substrate processing section 6. The second interface section 5 includes an immersion tank 51, a second transfer device 52, a third transfer device 53, and a second delivery section 54.

The immersion tank 51 is disposed outside the moving range of the first transfer arm 43b. For example, the immersion tank 51 is disposed at a position shifted toward the positive side of the Y-axis with respect to the processing tank. The immersion tank 51 stores a second rinse solution into which the lot L is to be immersed. The second rinse solution is, for example, deionized water (DIW). The substrate W is held in the second rinse solution until the substrate W is pulled up from the second rinse solution by the third transfer device 53. Because the substrate W is present below the liquid surface of the second rinse solution, the surface tension of the second rinse solution does not act on the substrate W, and collapse of the uneven pattern of the substrate W can be prevented.

The second transfer device 52 includes a Y-axis driving device 52a, a Z-axis driving device 52b, and a second transfer arm 52c.

The Y-axis driving device 52a is disposed on the positive side of the X-axis in the second interface section 5. The Y-axis driving device 52a extends along the Y-axis from the second interface section 5 to the batch processing section 4. The Y-axis driving device 52a moves the Z-axis driving device 52b and the second transfer arm 52c along the Y-axis. The Y-axis driving device 52a may include a ball screw.

The Z-axis driving device 52b is movably attached to the Y-axis driving device 52a. The Z-axis driving device 52b moves the second transfer arm 52c along the Z-axis. The Z-axis driving device 52b may include a ball screw.

The second transfer arm 52c is movably attached to the Z-axis driving device 52b. The second transfer arm 52c receives and holds the lot L from the first transfer arm 43b. The second transfer arm 52c holds the plurality of substrates W at the first pitch P1 along the Y-axis, and holds each of the plurality of substrates W vertically. The second transfer arm 52c is moved along the Y-axis and Z-axis by the Y-axis driving device 52a and the Z-axis driving device 52b. The second transfer arm 52c is configured to be movable to a plurality of positions including a handover position, an immersion position, and a standby position.

The handover position is a position where the lot L is handed over between the first transfer arm 43b and the second transfer arm 52c. The handover position is located on the negative side of the Y-axis and the positive side of the Z-axis.

The immersion position is a position where the lot L is immersed in the immersion tank 51. The immersion position is located on the positive Y-axis side of the handover position and the negative Z-axis side of the handover position.

The standby position is a position where the second transfer arm 52c waits when the transfer of the lot L and the immersion of the lot L into the immersion tank 51 are not performed. The standby position is located directly below the handover position (the negative side of the Z-axis) and is a position not interfering with the movement of the first transfer arm 43b. In this case, the second transfer arm 52c can move to the handover position by only moving upward (to the positive side of the Z-axis), and thus throughput is improved. The standby position may be a position that is the same as the immersion position. This can prevent particles that can be generated by the operation of the first transfer device 43 from adhering to the second transfer arm 52c. The standby position may be a position directly above the immersion position (the positive side of the Z-axis). As has been described, by setting the standby position at a position different from the handover position, contact between the first transfer arm 43b and the second transfer arm 52c can be prevented.

The second transfer device 52 moves the second transfer arm 52c to the immersion position or the standby position while the first transfer device 43 is operating. With this, contact between the first transfer arm 43b and the second transfer arm 52c can be prevented.

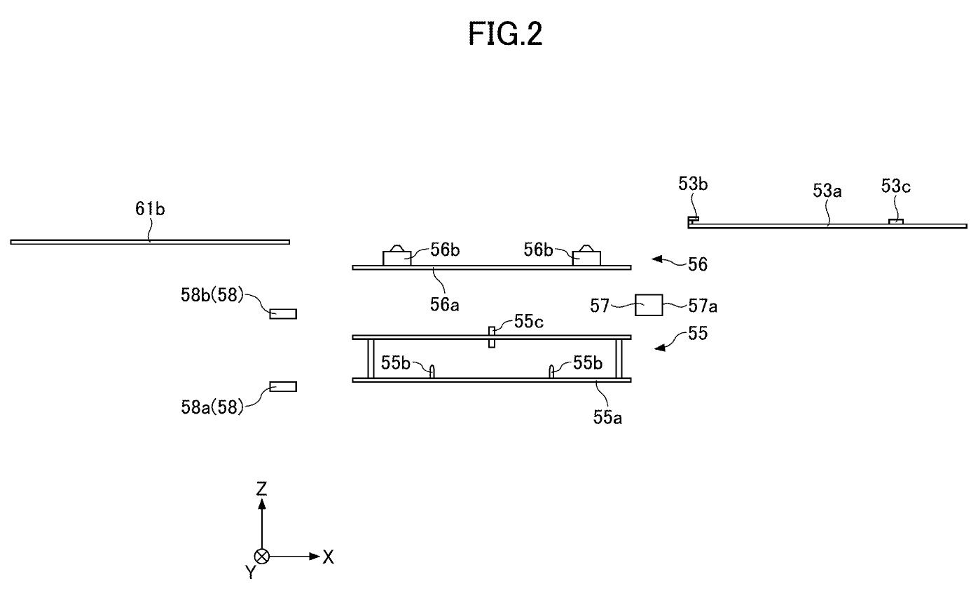

The third transfer device 53 includes a multi-axis (for example, six-axis) vertically articulated robot, and includes a third transfer arm 53a at its tip. The third transfer arm 53a includes a holding claw 53b (see FIG. 2) capable of holding one substrate W and a clamp member 53c (see FIG. 2). The clamp member 53c is configured to be movable between a closed position where the peripheral edge of the substrate W is clamped and an open position where the clamp of the substrate W is released. The third transfer arm 53a can take a suitable position and orientation in a three-dimensional space while holding the substrate W by the holding claw 53b and the clamp member 53c. The third transfer device 53 transfers the substrate W between the second transfer arm 52c at the immersed position and the second delivery section 54. At this time, because the immersion tank 51 is disposed outside the moving range of the first transfer arm 43b, the first transfer arm 43b and the third transfer arm 53a do not interfere. With this, one of the first transfer device 43 or the third transfer device 53 can be operated independently regardless of the operating state of the other. Therefore, the first transfer device 43 and the third transfer device 53 can be operated at suitable timings, thereby reducing the time required for transferring the substrate W. As a result, the productivity of the substrate processing system 1 is improved.

The second delivery section 54 is adjacent to the single-substrate processing section 6. The second delivery section 54 is disposed on the negative side of the X-axis in the second interface section 5. The second delivery section 54 receives the substrate W from the third transfer device 53 and temporarily stores the substrate W until the substrate W is delivered to the single-substrate processing section 6. The substrate W taken out of the immersion tank 51 is mounted on the second delivery section 54. Preferably, the substrate W mounted on the second delivery section 54 is in a state in which the surface of the substrate W is wet with the second rinse solution, for example. In this case, the surface tension of the second rinse solution does not act on the substrate W, and collapse of the uneven pattern of the substrate W can be prevented. The number of second delivery sections 54 may be one or more. The second delivery sections 54 may be disposed in multiple stages (for example, three stages) along the Z-axis. Details of the second delivery section 54 will be described later.

The single-substrate processing section 6 is disposed on the negative X-axis side of the second interface section 5. The single-substrate processing section 6 is disposed on the positive Y-axis side of the carry-in/out section 2, the first interface section 3, and the batch processing section 4. The single-substrate processing section 6 processes the substrates W one by one. The single-substrate processing section 6 includes a fourth transfer device 61, a liquid treatment device 62, and a drying device 63.

The fourth transfer device 61 includes a guide rail 61a and a fourth transfer arm 61b.

The guide rail 61a is disposed on the negative side of the Y-axis in the single-substrate processing section 6. The guide rail 61a extends along the X-axis in the single-substrate processing section 6.

The fourth transfer arm 61b moves along the guide rail 61a. The fourth transfer arm 61b rotates around the Z-axis. The fourth transfer arm 61b transfers the substrate W between the second delivery section 54, the liquid treatment device 62, the drying device 63, and the first delivery section 33. The number of fourth transfer arms 61b may be one or greater, and in the latter case, the fourth transfer device 61 transfers a plurality of (for example, five) substrates W collectively.

The liquid treatment device 62 is disposed on the positive side of the X-axis and the positive side of the Y-axis in the single-substrate processing section 6. The liquid treatment device 62 is a single-substrate type, and treats the substrates W one by one with the treatment liquid. The liquid treatment device 62 is disposed in multiple stages (for example, three stages) along the Z-axis. With this, a plurality of substrates W can be simultaneously treated with the treatment liquid. The treatment liquid may be plural, and may be, for example, pure water such as DIW and a drying liquid having a lower surface tension than pure water. The drying liquid may be alcohol such as isopropyl alcohol (IPA).

The drying device 63 is disposed adjacent to the liquid treatment device 62 on the negative side of the X-axis. In this case, the Y-axis positive end face of the single-substrate processing section 6 can be disposed so as to be flush or substantially flush with the Y-axis positive end face of the second interface section 5. Therefore, almost no dead space is generated, and the footprint of the substrate processing system 1 can be reduced. With respect to the above, when the drying device 63 is disposed adjacent to the liquid treatment device 62 on the positive side of the Y-axis, the Y-axis positive end face of the single-substrate processing section 6 protrudes from the Y-axis positive end face of the second interface section 5, and a dead space can be generated. The drying device 63 is a single-substrate type, and the substrates W are dried one by one with a supercritical fluid. The drying device 63 is disposed in multiple stages (for example, three stages) along the Z-axis. With this, a plurality of substrates W can be dried simultaneously.

Both the liquid treatment device 62 and the drying device 63 are not required to be a single-substrate type, the liquid treatment device 62 may be a single-substrate type, and the drying device 63 may be a batch type. The drying device 63 may collectively dry a plurality of substrates W with a supercritical fluid. The number of substrates W to be processed collectively in the drying device 63 may be greater than or equal to the number of substrates W to be processed collectively in the liquid treatment device 62, but may be less. A device other than the liquid treatment device 62 and the drying device 63 may be disposed in the single-substrate processing section 6.

The control circuit 9 is, for example, a computer. The control circuit 9 includes an arithmetic unit 91 such as a central processing unit (CPU) and a storage unit 92 such as a memory. The storage unit 92 stores programs for controlling various processes to be executed in the substrate processing system 1. The control circuit 9 controls the operation of the substrate processing system 1 by causing the arithmetic unit 91 to execute the programs stored in the storage unit 92.

The control circuit 9 includes an electronic circuit, such as a CPU, a field programmable gate array (FPGA), or an application specific integrated circuit (ASIC), and performs various control operations described herein by executing instruction codes stored in the memory or by a circuit design for special applications.

In the substrate processing system 1, the substrate W is transferred in the order of the carry-in/out section 2, the first interface section 3, the batch processing section 4, the second interface section 5, and the single-substrate processing section 6, and returns to the carry-in/out section 2.

### Second Delivery Section

An example of the second delivery section 54 will be described with reference to FIG. 2. FIG. 2 illustrates the example of the second delivery section 54. As illustrated in FIG. 2, the second delivery section 54 includes a delivery table 55, an alignment table 56, a substrate position changing section 57, and a detection section 58.

The delivery table 55 includes a bottom plate 55a, a plurality of pins 55b, and a nozzle 55c. The plurality of pins 55b are provided on the bottom plate 55a. The number of pins 55b is, for example, three. The number of pins 55b may be four or greater. A surface including the upper end of each of the pins 55b is horizontal. The plurality of pins 55b horizontally support, from below, the substrate W above the bottom plate 55a. The nozzle 55c discharges pure water supplied through a pure water supply line (which is not illustrated). With this, pure water is supplied to the upper surface of the substrate W supported by the plurality of pins 55b.

The alignment table 56 is provided above the delivery table 55. The alignment table 56 includes a bottom plate 56a and a plurality of supports 56b. The plurality of supports 56b are provided on the bottom plate 56a. The number of supports 56b is, for example, four. The number of supports 56b may be three, or five or greater. Each of the supports 56b has a truncated cone-shaped projection, the outer diameter of which decreases from the lower end to the upper end. The surface including the upper end of each support 56b is horizontal. The plurality of supports 56b support, from below, the substrate W above the bottom plate 56a. The plurality of supports 56b support the substrate W at the tapered portions of the projections. With this, the substrate W is centered. The center position of the substrate W supported by the plurality of supports 56b on the alignment table 56 matches the center position of the substrate W supported by the plurality of pins 55b on the delivery table 55.

The substrate position changing section 57 has a contact surface 57a that can contact the substrate W held by the third transfer arm 53a. The contact surface 57a is provided on the positive X-axis side of the substrate position changing section 57. The contact surface 57a is, for example, a flat surface. The contact surface 57a may be a curved surface that is convex on the positive side of the X-axis. The third transfer arm 53a, while holding the substrate W, moves to the same height as the contact surface 57a on the positive X-axis side of the substrate position changing section 57, and then moves horizontally toward the negative side of the X-axis toward the contact surface 57a, thereby bringing the end of the substrate W into contact with the contact surface 57a and aligning the substrate W. The substrate position changing section 57 is disposed on the positive X-axis side of the delivery table 55. In this case, the time required for the third transfer arm 53a to align the substrate W can be shortened. The substrate position changing section 57 is disposed above the delivery table 55 and below the alignment table 56. In this case, the moving distance of the third transfer arm 53a until the substrate W is delivered to the delivery table 55 after the third transfer arm 53a performs the operation of aligning the substrate W is shortened, so that the time required for the movement of the third transfer arm 53a can be shortened. The position where the substrate position changing section 57 is disposed is not limited to the position illustrated in FIG. 2, and may be disposed at a different position as long as the third transfer arm 53a is accessible. The substrate position changing section 57 may be disposed on the negative X-axis side of the delivery table 55. The substrate position changing section 57 may be disposed below the delivery table 55 or above the alignment table 56.

The detection section 58 may include a light projection section 58a and a light reception section 58b. The light projection section 58a and the light reception section 58b face each other across a path through which the substrate W passes when the fourth transfer arm 61b moves toward the negative side of the X-axis after receiving the substrate W from the delivery table 55. For example, the light projection section 58a may be disposed below the light reception section 58b. The light projection section 58a may be disposed above the light reception section 58b. The detection section 58 detects the position of the peripheral edge of the substrate W when the fourth transfer arm 61b is moving along the negative X-axis while holding the substrate W. The light projection section 58a is a light source such as a light emitting diode (LED). The light reception section 58b is an imaging device such as a linear image sensor. A plurality of detection sections 58 may be provided. In this case, detection accuracy is improved.

### Substrate Processing Method

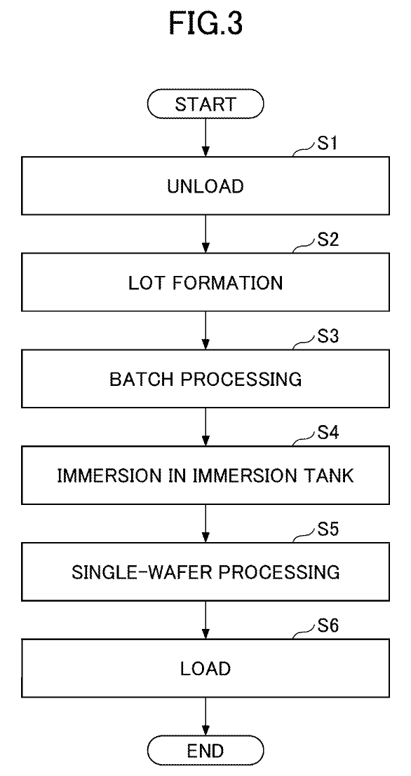

Referring to FIGS. 1 and 3, an example of a substrate processing method performed in the substrate processing system 1 will be described. FIG. 3 is a flowchart illustrating the example of the substrate processing method. The process illustrated in FIG. 3 is performed under the control of the control circuit 9.

First, the cassette C is carried into the carry-in/out section 2 in a state where a plurality of substrates W are accommodated, and is mounted on the load port 21. Inside the cassette C, the substrates W are held horizontally, and are held at the second pitch P2 (P2=N×P1) along the Z-axis. N is a natural number greater than or equal to two. N is two in the present embodiment, but may be three or greater.

Next, the cassette transfer device 24 transfers the cassette C from the load port 21 to the loader 23. The cover of the cassette C transferred to the loader 23 is opened by the cover opening/closing mechanism.

Next, the substrate transfer device 31 receives the substrates W accommodated in the cassette C (S1 in FIG. 3) and transfers the substrates to the lot formation section 32.

Next, the lot formation section 32 holds the plurality of substrates W at the first pitch P1 (P1=P2/N) to form the lot L (S2 in FIG. 3). One lot L includes, for example, the substrates W of M cassettes C. Because the pitch of the substrates W narrows from the second pitch P2 to the first pitch P1, the number of substrates W to be processed collectively can be increased.

Next, the first transfer device 43 receives the lot L from the lot formation section 32 and transfers it to the treatment tool 44.

Next, the treatment tool 44 descends from above the chemical solution tank 41, immerses the lot L in the chemical solution, and performs treatment with the chemical solution (S3 in FIG. 3). Subsequently, the treatment tool 44 rises to pull up the lot L from the chemical solution, and then moves toward the upper side of the rinse solution tank 42 on the negative side of the X-axis.

Next, the treatment tool 44 descends from above the rinse solution tank 42, immerses the lot L in the first rinse solution, and performs treatment with the rinse solution (S3 in FIG. 3). Subsequently, the treatment tool 44 rises to pull up the lot L from the first rinse solution. Then, the first transfer device 43 receives the lot L from the treatment tool 44 and delivers it to the second transfer device 52.

Next, the second transfer arm 52c of the second transfer device 52 moves to the positive side of the Y-axis and descends from above the immersion tank 51 to immerse the lot L in the second rinse solution (S4 in FIG. 3). The plurality of substrates W of the lot L are held in the second rinse solution until they are pulled up from the second rinse solution by the third transfer device 53. Because the substrate W is present below the liquid surface of the second rinse solution, surface tension of the second rinse solution does not act on the substrate W, and collapse of the uneven pattern of the substrate W can be prevented.

Next, the third transfer device 53 transfers the substrates W of the lot L held by the second transfer arm 52c in the second rinse solution to the second delivery section 54. The third transfer device 53 transfers, for example, the substrates W one by one to the second delivery section 54. In the second delivery section 54, in order to prevent collapse of the uneven pattern due to drying of the upper surface of the substrate W, pure water is discharged onto the upper surface of the substrate W, and a liquid film of pure water is formed.

Next, the fourth transfer device 61 receives the substrate W from the second delivery section 54 and transfers it to the liquid treatment device 62.

Next, the liquid treatment device 62 treats the substrate W one by one with liquid (S5 in FIG. 3). The liquid may be plural, and, for example, may be pure water such as DIW and a drying liquid having a lower surface tension than pure water. The drying liquid may be, for example, alcohol such as IPA. The liquid treatment device 62 supplies the pure water and the drying liquid to the upper surface of the substrate W in this order to form a liquid film of the drying liquid.

Next, the fourth transfer device 61 receives the substrate W from the liquid treatment device 62 and holds the substrate W horizontally with the liquid film of the drying liquid facing upward. The fourth transfer device 61 transfers the substrate W from the liquid treatment device 62 to the drying device 63.

Next, the drying device 63 dries the substrates W one by one with the supercritical fluid (S5 in FIG. 3). The drying liquid can be replaced with the supercritical fluid, and collapse of the unevenness pattern of the substrates W due to surface tension of the drying liquid can be prevented. Because supercritical fluid requires a pressure vessel, it is performed in the single-substrate processing instead of the batch processing in order to reduce the size of the pressure vessel.

Here, the drying device 63 is a single-substrate type in the present embodiment, but it may be a batch type as described above. The batch-type drying device 63 collectively dries, with supercritical fluid, a plurality of substrates W on which liquid films have been formed. While the single-substrate type drying device 63 includes a single transfer arm for holding the substrate W, the batch-type drying device 63 includes a plurality of transfer arms.

In the present embodiment, the drying device 63 dries the substrate W by supercritical drying, but the drying method is not particularly limited. The drying method may be, for example, spin drying, scan drying, or water repellent drying as long as collapse of the uneven pattern of the substrate W can be prevented. In the spin drying, the liquid treatment device 62 rotates the substrate W and spins off the drying liquid from the substrate W by centrifugal force, thereby removing the drying liquid from the upper surface of the substrate W. The scan drying rotates the substrate W while moving, from the center of the substrate W toward the outer periphery of the substrate W, a position where the drying liquid is supplied, thereby spinning off the liquid film from the substrate W by centrifugal force. The scan drying may further move, from the center of the substrate W toward the outer periphery of the substrate W, a position where the drying gas such as nitrogen gas is supplied so as to follow the position where the drying liquid is supplied.

Next, the fourth transfer device 61 receives the substrate W from the drying device 63 and transfers it to the first delivery section 33.

Next, the substrate transfer device 31 receives the substrate W from the first delivery section 33 and accommodates it in the cassette C (S6 in FIG. 3). The cassette C is carried out from the carry-in/out section 2 with the plurality of substrates W being accommodated therein. This completes the process illustrated in FIG. 3.

### Method of Adjusting the Substrate Transfer Position

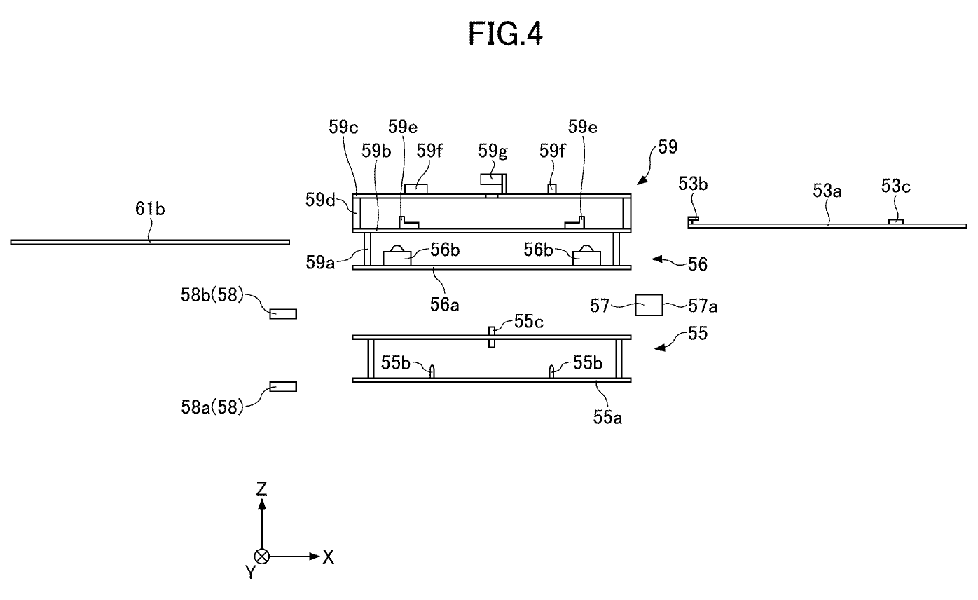

With reference to FIGS. 4 to 25, an example of a method of adjusting a substrate transfer position will be described. FIGS. 4 to 25 are views illustrating an example of the method of adjusting the substrate transfer position. The method of adjusting the substrate transfer position illustrated in FIGS. 4 to 25 is performed by using a dummy substrate as the substrate W, for example, before processing on a product substrate is performed. The product substrate may be used instead of the dummy substrate. The method of adjusting the substrate transfer position illustrated in FIGS. 4 to 25 is performed, for example, during periodic maintenance of the substrate processing system 1.

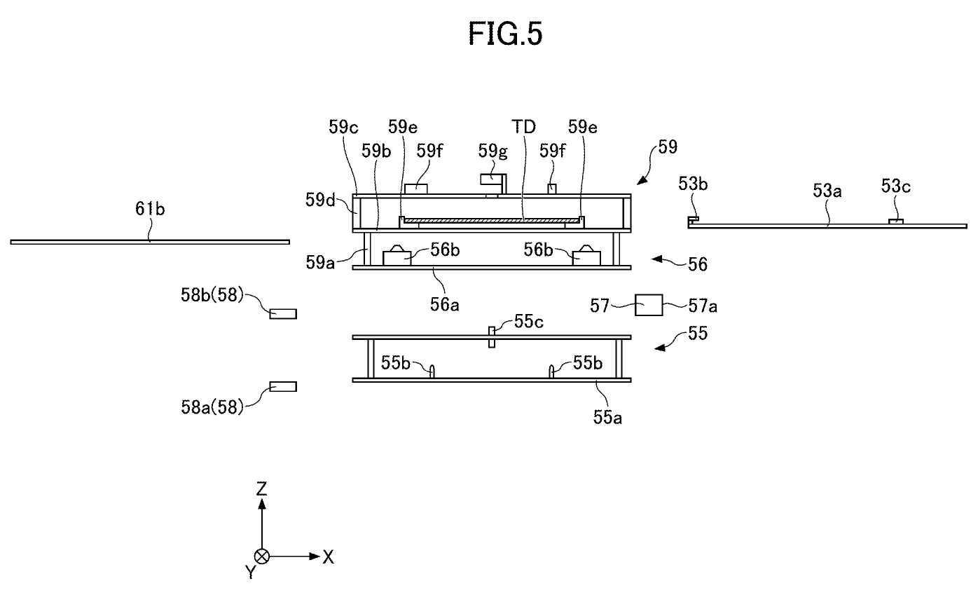

First, as illustrated in FIG. 4, an adjustment jig 59 is mounted on the alignment table 56. For example, the adjustment jig 59 is mounted on the alignment table 56 by an operator. The adjustment jig 59 is detachably attached to the alignment table 56. In this case, because a single adjustment jig 59 can be used in a plurality of substrate processing systems 1, it is not necessary to prepare the adjustment jig 59 for each of the plurality of substrate processing systems 1. The adjustment jig 59 includes a leg 59a, a bottom plate 59b, a top plate 59c, a connection 59d, a reference block 59e, a laser displacement meter 59f, and a camera 59g. Four legs 59a are provided, for example. Each of the legs 59a extends downward from the lower surface of the bottom plate 59b at the periphery of the bottom plate 59b. Each of the legs 59a is provided on the upper surface of the alignment table 56. The bottom plate 59b is provided parallel to the bottom plate 56a of the alignment table 56 by the legs 59a. The top plate 59c is provided parallel to the bottom plate 59b. Four connections 59d are provided, for example. Each of the connections 59d connects the bottom plate 59b and the top plate 59c at the peripheries of the bottom plate 59b and the top plate 59c. The reference block 59e is provided on the bottom plate 59b. The reference block 59e holds a target disk TD (see FIG. 5) at a reference position. The target disk TD is a plate member including an alignment mark on the top surface. The laser displacement meter 59f is attached to the top plate 59c. Three laser displacement meters 59f are provided, for example. The laser displacement meter 59f detects the vertical position of the target disk TD and its inclination with respect to the horizontal plane. The camera 59g is attached to the top plate 59c. The camera 59g detects the horizontal position of the target disk TD and its rotation around the vertical axis by imaging the alignment mark of the target disk TD.

Next, as illustrated in FIG. 5, the target disk TD is installed on the reference block 59e. For example, the target disk TD is installed on the reference block 59e by the operator. Next, the laser displacement meter 59f and the camera 59g detect the position of the target disk TD and transmit the detected position information to the control circuit 9. The control circuit 9 stores the received position information of the target disk TD as the reference position.

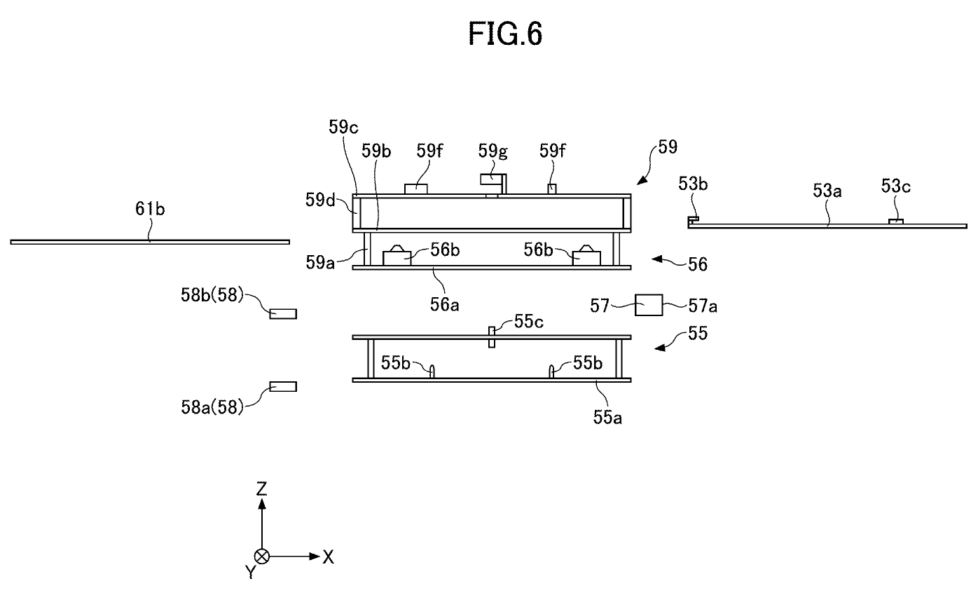

Next, as illustrated in FIG. 6, the target disk TD installed on the reference block 59e is removed. For example, the target disk TD is removed from the reference block 59e by the operator.

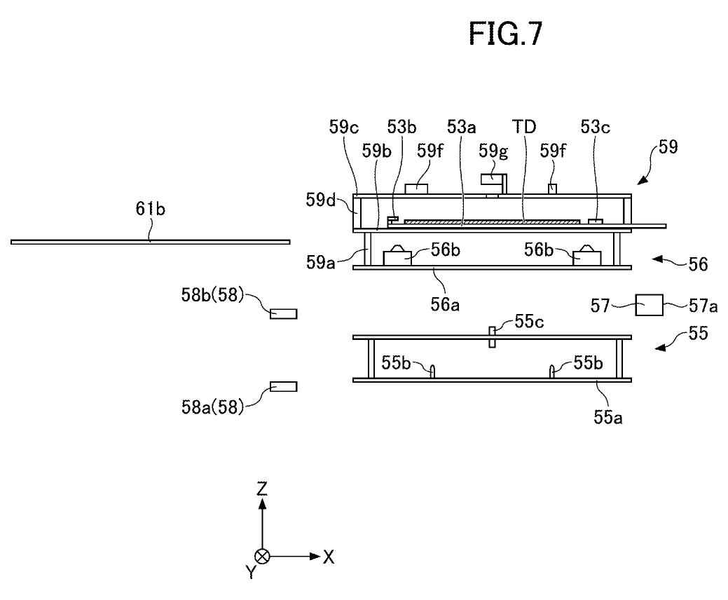

Next, as illustrated in FIG. 7, while the third transfer arm 53a holds the target disk TD, the third transfer arm 53a moves to a position (hereinafter referred to as a “first insertion position”) directly above the position where the substrate W is delivered to the alignment table 56. Next, the laser displacement meter 59f and the camera 59g detect the position of the target disk TD and transmit the detected position information to the control circuit 9. Based on the received position information of the target disk TD and the reference position, the control circuit 9 corrects the first insertion position so that the received position of the target disk TD matches the reference position.

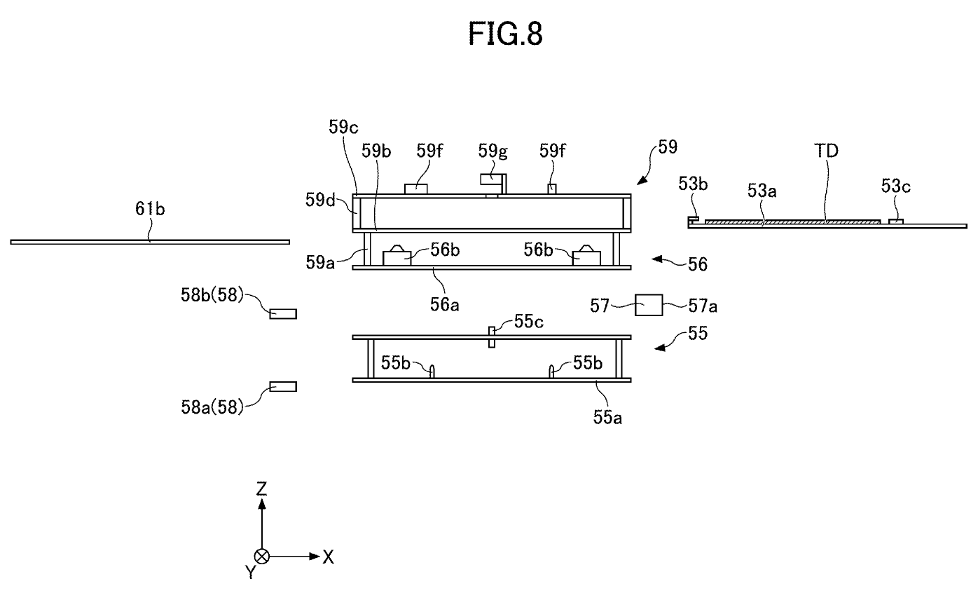

Next, as illustrated in FIG. 8, the third transfer arm 53a retracts to the positive X-axis side of the alignment table 56 while holding the target disk TD.

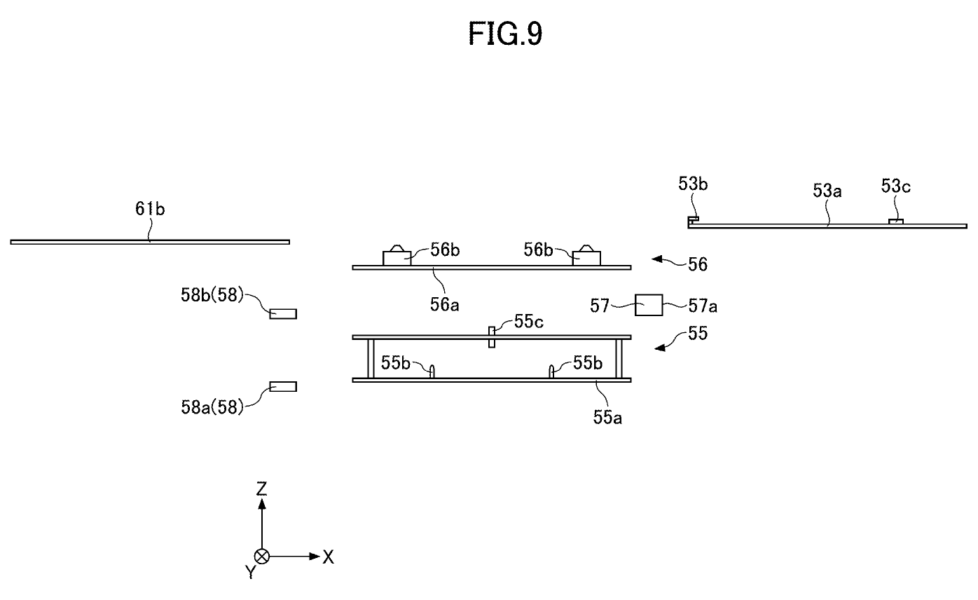

Next, as illustrated in FIG. 9, the target disk TD is removed from the third transfer arm 53a, and the adjustment jig 59 is removed from the alignment table 56. For example, the target disk TD is removed from the third transfer arm 53a by the operator. For example, the adjustment jig 59 is removed from the alignment table 56 by the operator.

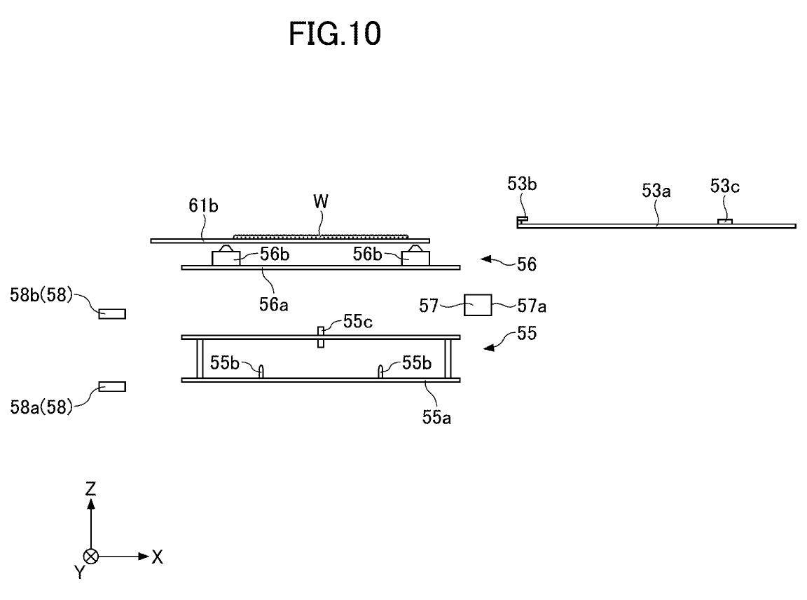

Next, as illustrated in FIG. 10, the fourth transfer arm 61b, while holding the substrate W, moves to a position (hereinafter referred to as a “second insertion position”) directly above the position where the substrate W is delivered to the alignment table 56. The substrate W is, for example, the dummy substrate acquired from the first delivery section 33 by the fourth transfer arm 61b. The substrate W may be the dummy substrate mounted on the fourth transfer arm 61b by the operator.

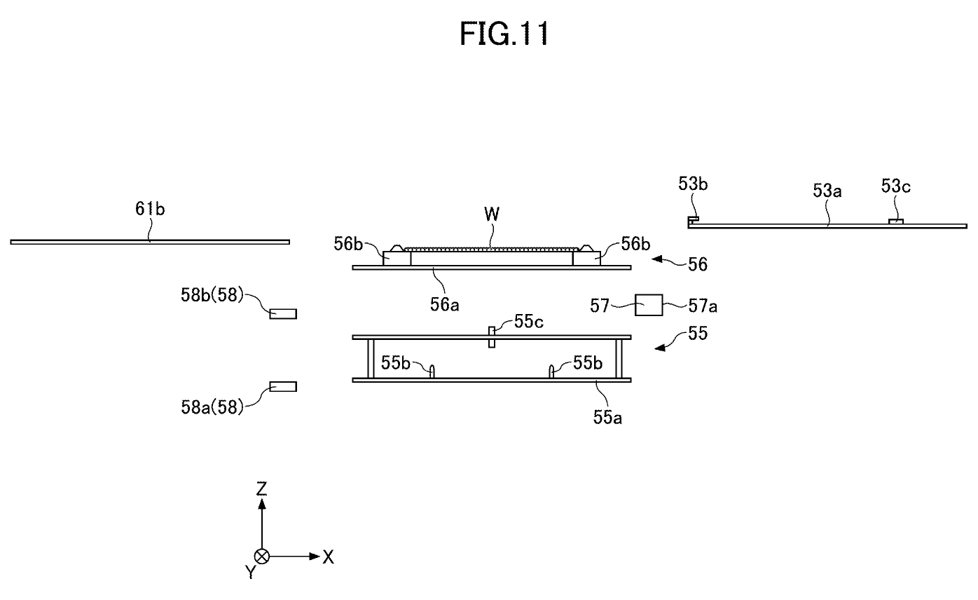

Next, as illustrated in FIG. 11, the fourth transfer arm 61b descends while holding the substrate W and delivers the substrate W to the plurality of supports 56b. The plurality of supports 56b support the substrate W at the tapered portions of the projections. With this, the substrate W is centered. After delivering the substrate W to the plurality of supports 56b, the fourth transfer arm 61b retracts to the negative X-axis side of the alignment table 56.

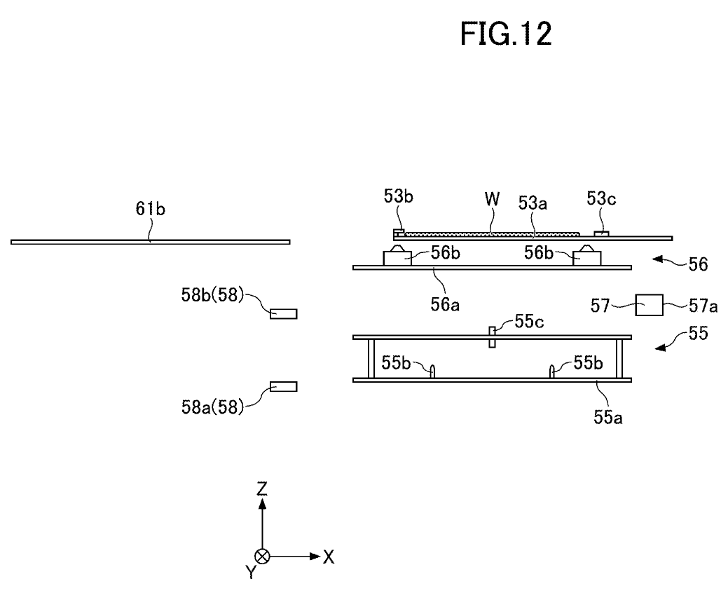

Next, as illustrated in FIG. 12, the third transfer arm 53a receives the substrate W supported by the plurality of supports 56b. At this time, the third transfer arm 53a does not hold the substrate W by the holding claw 53b and the clamp member 53c.

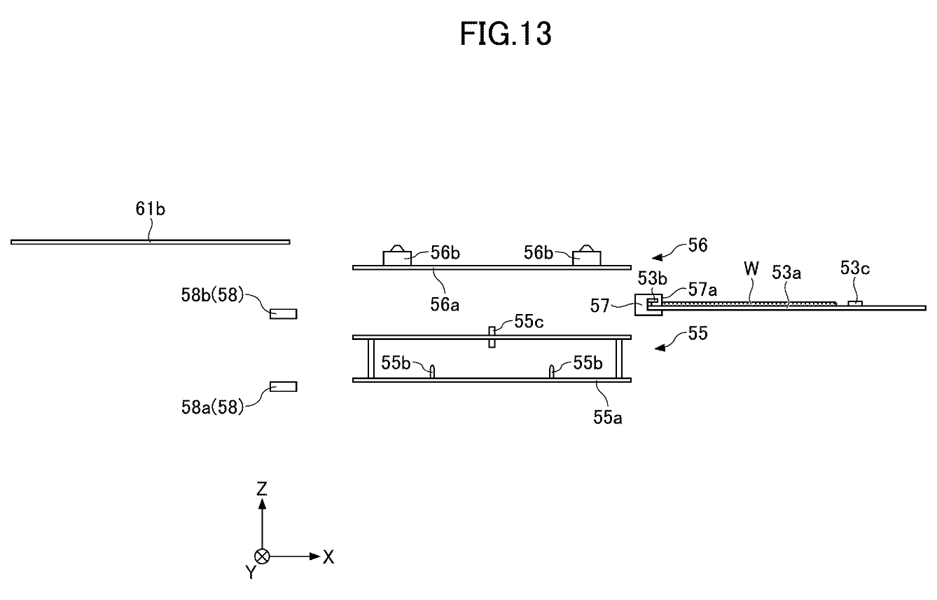

Next, as illustrated in FIG. 13, the third transfer arm 53a, while holding the substrate W, pushes the substrate W against the contact surface 57a of the substrate position changing section 57, thereby relatively moving the substrate W to the positive side of the X-axis with respect to the third transfer arm 53a.

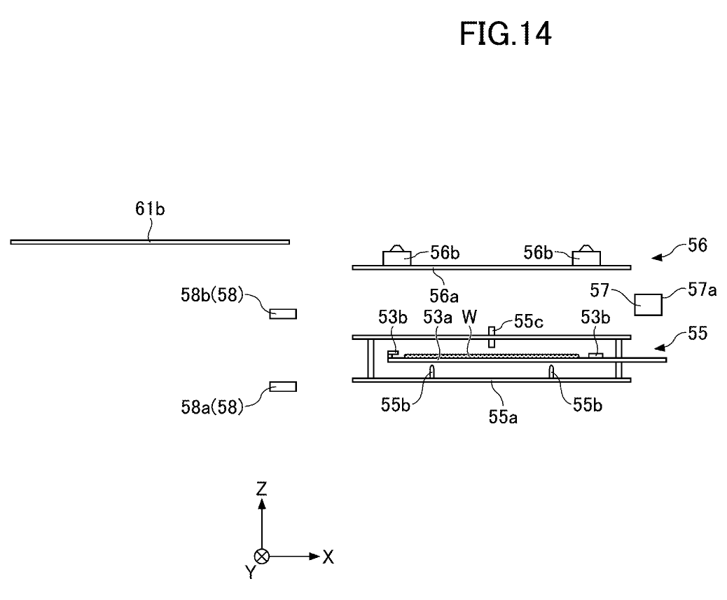

Next, as illustrated in FIG. 14, the third transfer arm 53a, while holding the substrate W, moves to a position (hereinafter referred to as a “third insertion position”) directly above the position where the substrate W is delivered to the delivery table 55.

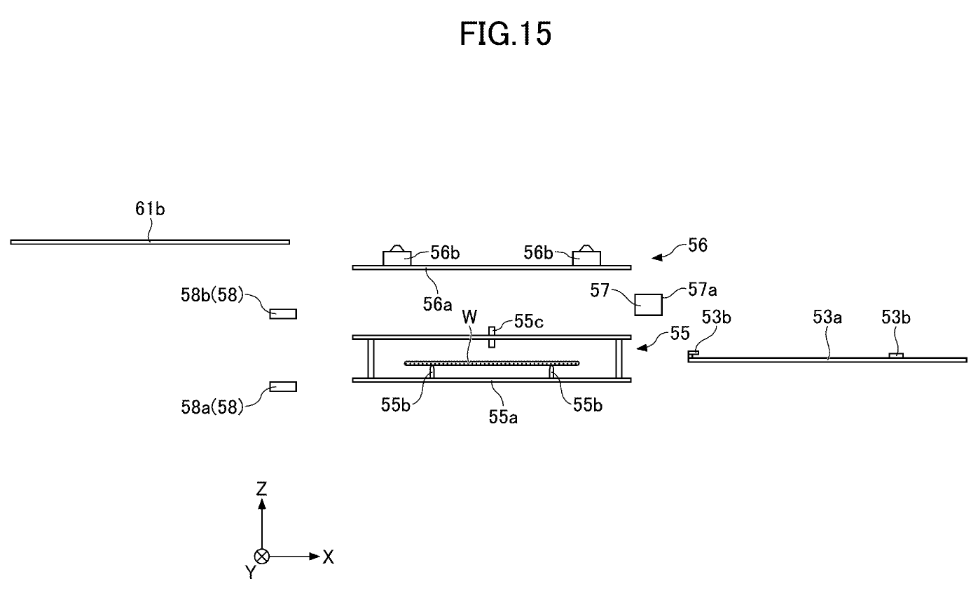

Next, as illustrated in FIG. 15, the third transfer arm 53a descends while holding the substrate W and delivers the substrate W to the plurality of pins 55b. The plurality of pins 55b horizontally support, from below, the substrate W above the bottom plate 55a. After delivering the substrate W to the plurality of pins 55b, the third transfer arm 53a retracts to the positive X-axis side of the delivery table 55.

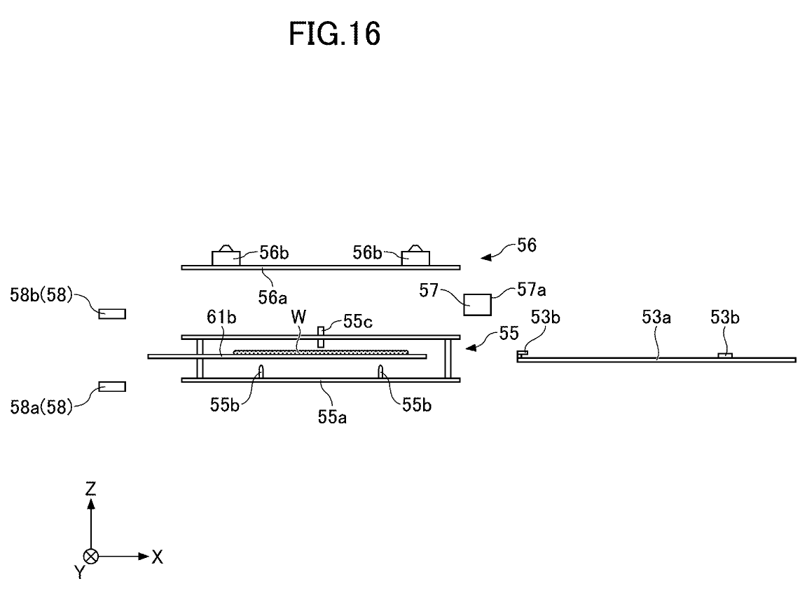

Next, as illustrated in FIG. 16, the fourth transfer arm 61b receives the substrate W supported by the plurality of pins 55b.

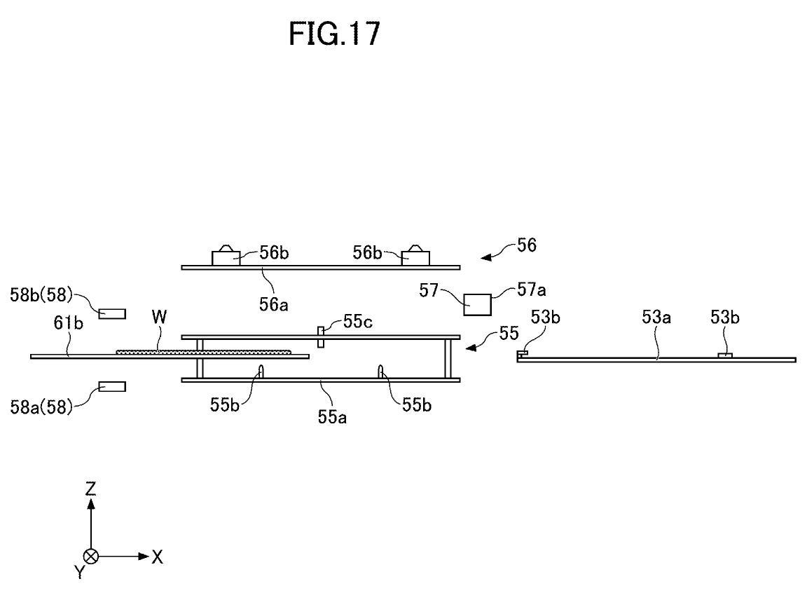

Next, as illustrated in FIG. 17, the fourth transfer arm 61b retracts to the negative X-axis side of the delivery table 55 while holding the substrate W. At this time, the detection section 58 detects a shift amount, in the horizontal direction, of the substrate W held by the fourth transfer arm 61b moving toward the negative side of the X-axis, and transmits the detected shift amount to the control circuit 9. The control circuit 9 corrects the third insertion position (the horizontal position) of the third transfer arm 53a so that the received shift amount becomes 0 (zero).

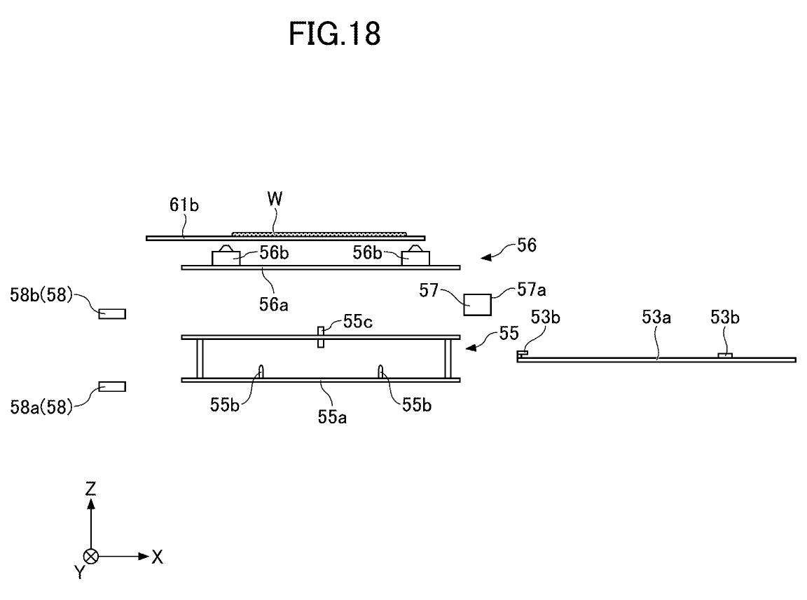

Next, as illustrated in FIG. 18, the fourth transfer arm 61b moves to the second insertion position while holding the substrate W.

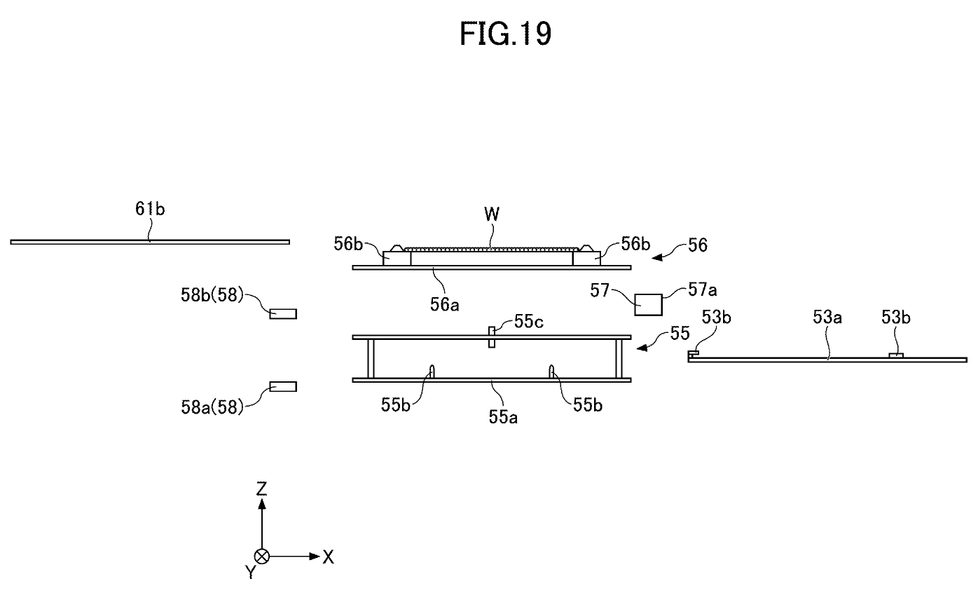

Next, as illustrated in FIG. 19, the fourth transfer arm 61b descends while holding the substrate W, and delivers the substrate W to the plurality of supports 56b. The plurality of supports 56b support the substrate W at the tapered portions of the projections. With this, the substrate W is centered. After delivering the substrate W to the plurality of supports 56b, the fourth transfer arm 61b retracts to the negative X-axis side of the alignment table 56.

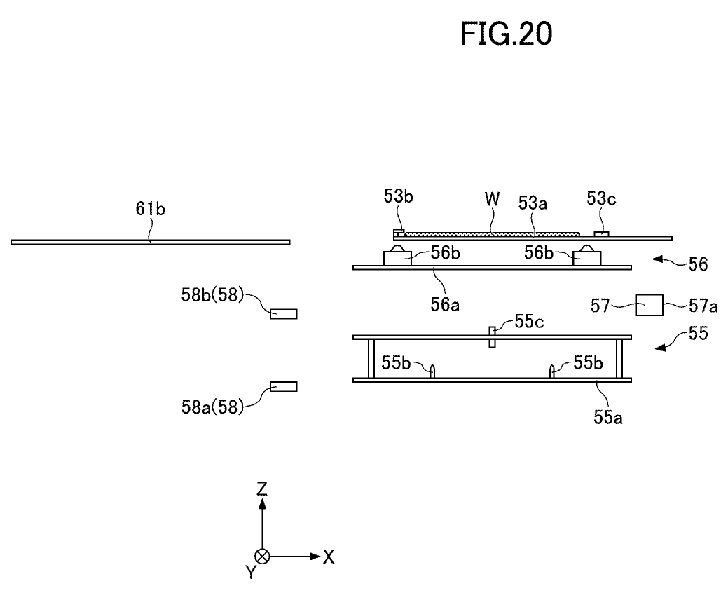

Next, as illustrated in FIG. 20, the third transfer arm 53a receives the substrate W supported by the plurality of supports 56b. At this time, the third transfer arm 53a does not hold the substrate W by the holding claw 53b and the clamp member 53c.

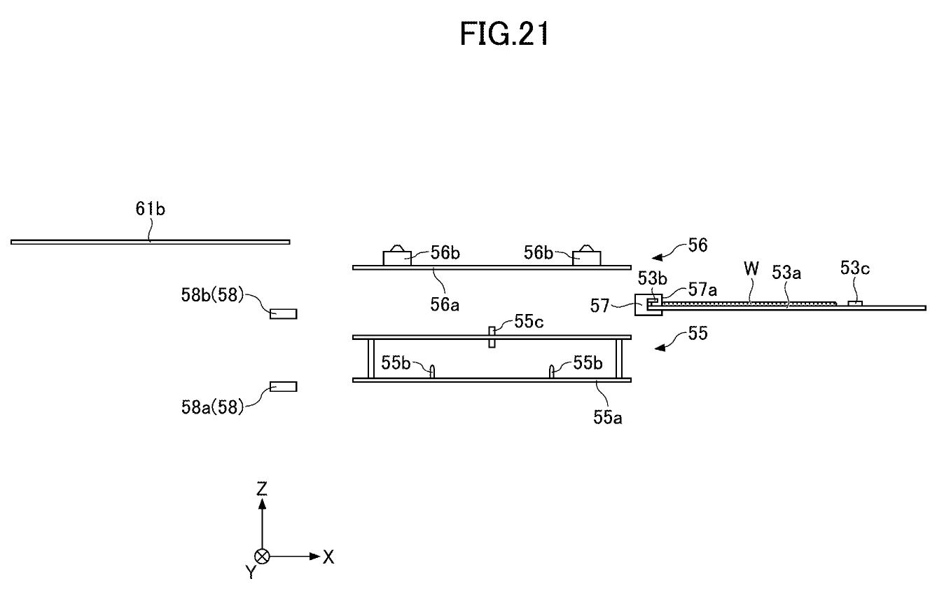

Next, as illustrated in FIG. 21, the third transfer arm 53a, while holding the substrate W, pushes the substrate W against the contact surface 57a of the substrate position changing section 57, thereby relatively moving the substrate W to the positive X-axis side with respect to the third transfer arm 53a.

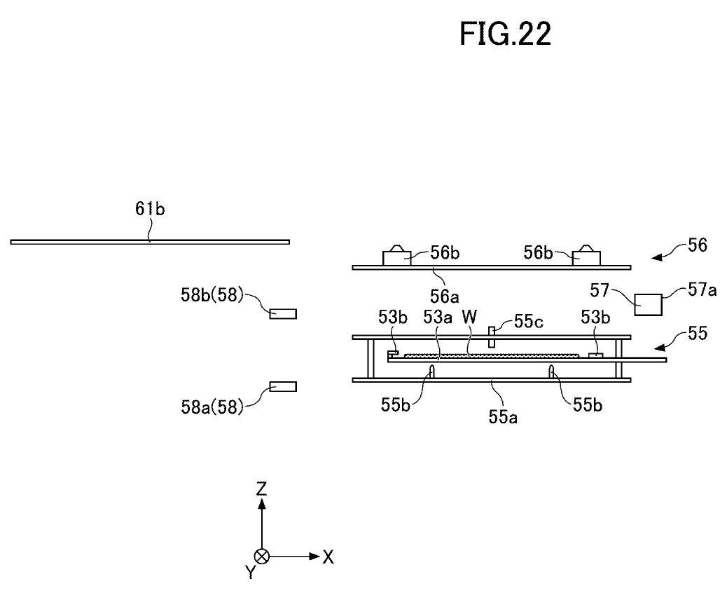

Next, as illustrated in FIG. 22, the third transfer arm 53a moves to the third insertion position while holding the substrate W.

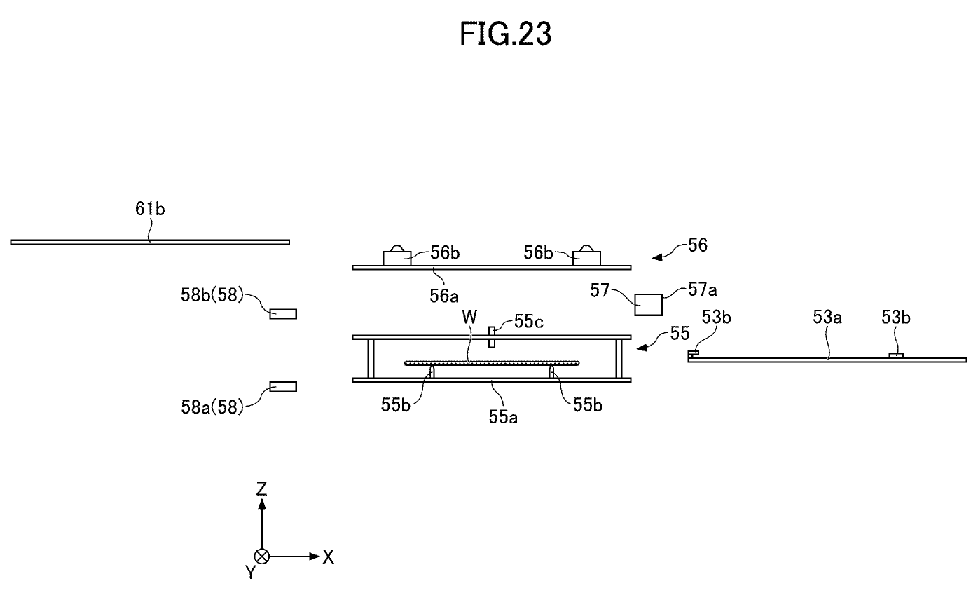

Next, as illustrated in FIG. 23, the third transfer arm 53a descends while holding the substrate W and delivers the substrate W to the plurality of pins 55b. The plurality of pins 55b support, from below, the substrate W horizontally above the bottom plate 55a. After delivering the substrate W to the plurality of pins 55b, the third transfer arm 53a retracts to the positive X-axis side of the delivery table 55.

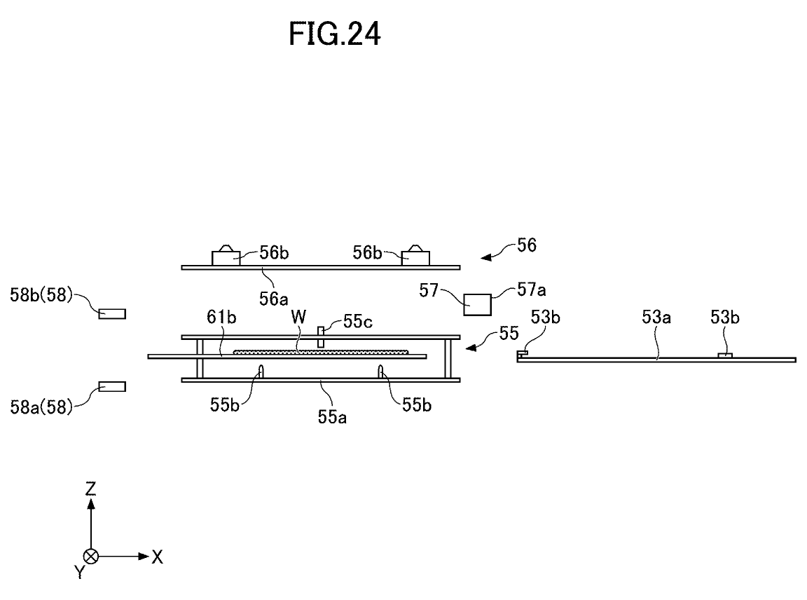

Next, as illustrated in FIG. 24, the fourth transfer arm 61b receives the substrate W supported by the plurality of pins 55b.

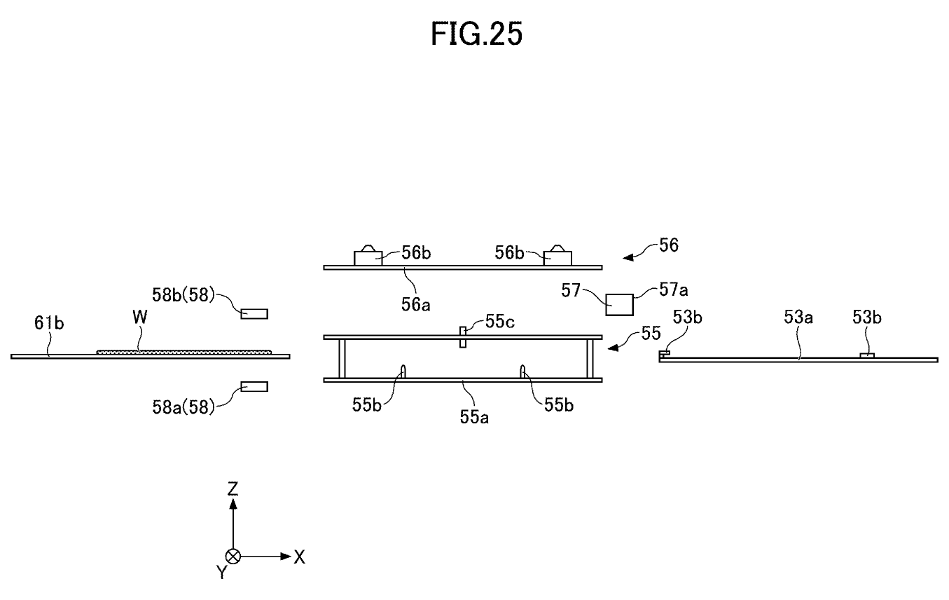

Next, as illustrated in FIG. 25, the fourth transfer arm 61b retracts to the negative X-axis side of the delivery table 55 while holding the substrate W. At this time, the detection section 58 detects the shift amount, in the horizontal direction, of the substrate W held by the fourth transfer arm 61b moving toward the negative side of the X-axis, and transmits the detected shift amount to the control circuit 9. The control circuit 9 determines whether the received shift amount is within the allowable range. If the received shift amount is within the allowable range, the method of adjusting the substrate transfer position ends. If the received shift amount is not within the allowable range, the control circuit 9 controls the third transfer arm 53a and the fourth transfer arm 61b so as to perform the operations illustrated in FIGS. 18 to 25 again.

According to the example of the method of adjusting the substrate transfer position described above, first, the shift amount of the substrate W with respect to the reference position is detected while the fourth transfer arm 61b holds the substrate W acquired from the delivery table 55. Then, based on the detected shift amount, the horizontal position when the third transfer arm 53a mounts the substrate W on the delivery table 55 is corrected. In this case, the shift of the substrate W transferred from the batch processing section 4 to the single-substrate processing section 6 can be reduced.

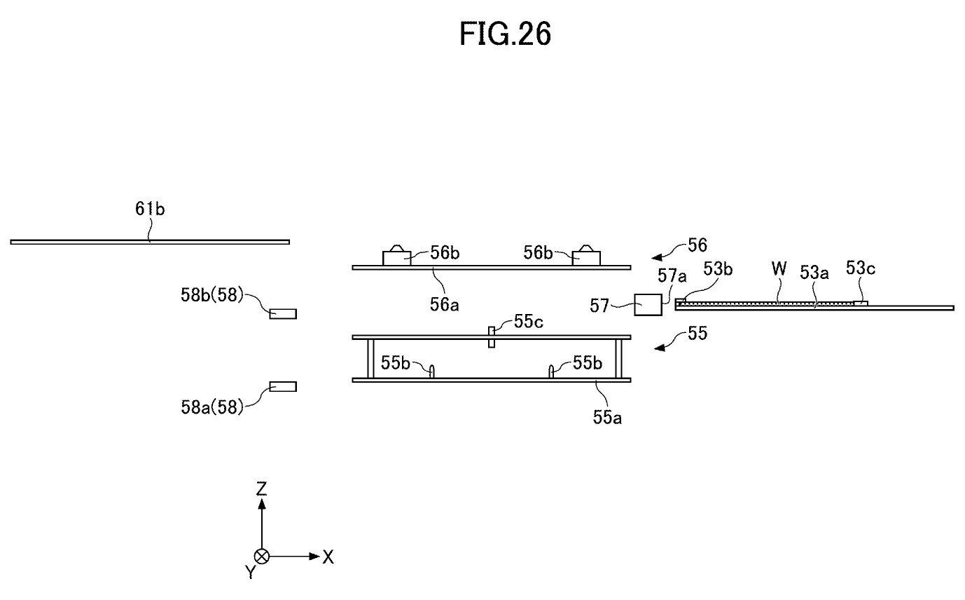

Referring to FIGS. 26 to 31, another example of the method of adjusting the substrate transfer position will be described. FIGS. 26 to 31 are views illustrating the other example of the method of adjusting the substrate transfer position. The method of adjusting the substrate transfer position illustrated in FIGS. 26 to 31 is performed using a product substrate as the substrate W when processing on the product substrate is performed. The method of adjusting the substrate transfer position illustrated in FIGS. 26 to 31 is performed for all substrates W in the lot L, for example. The method of adjusting the substrate transfer position illustrated in FIGS. 26 to 31 may be performed for some substrates W in the lot L, such as the first substrate W in the lot L.

First, as illustrated in FIG. 26, the third transfer arm 53a acquires the substrate W held in the vertical orientation in the immersion tank 51. The substrate W is, for example, a product substrate. When acquiring the substrate W from the immersion tank 51, the third transfer arm 53a holds the substrate W by the holding claw 53b and the clamp member 53c. Then, the third transfer arm 53a changes the orientation of the substrate W from the vertical orientation to the horizontal orientation.

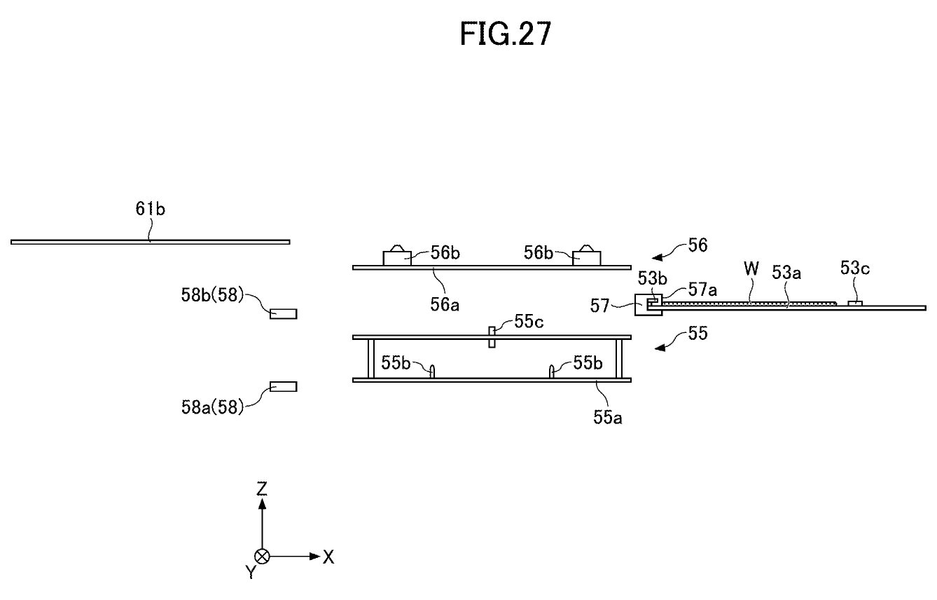

Next, as illustrated in FIG. 27, the third transfer arm 53a, while holding the substrate W in the horizontal orientation, pushes the substrate W against the contact surface 57a of the substrate position changing section 57, thereby relatively moving the substrate W to the positive side of the X-axis with respect to the third transfer arm 53a. Before pushing the substrate W against the contact surface 57a, the third transfer arm 53a moves the clamp member 53c from the closed position to the open position.

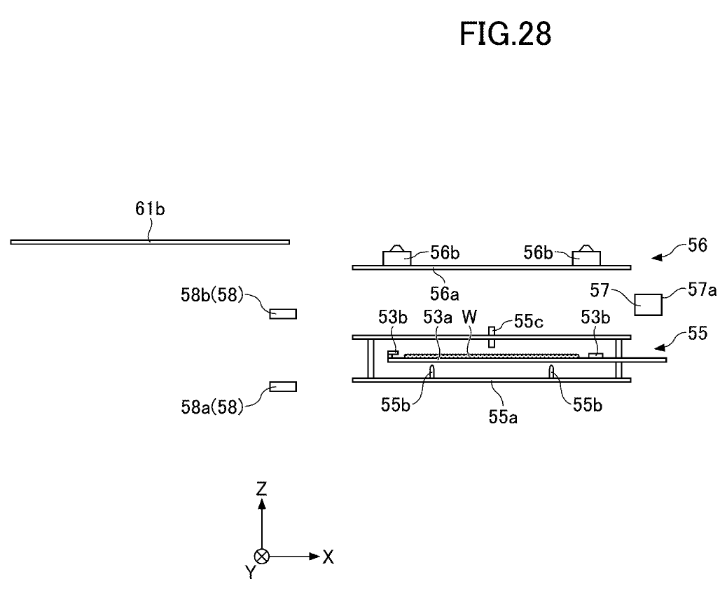

Next, as illustrated in FIG. 28, the third transfer arm 53a moves to the third insertion position while holding the substrate W.

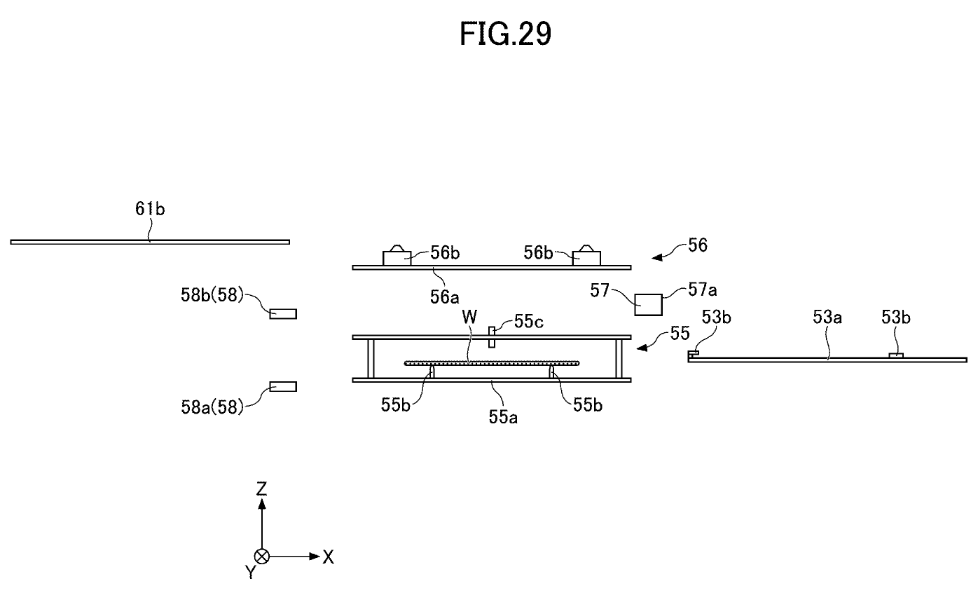

Next, as illustrated in FIG. 29, the third transfer arm 53a descends while holding the substrate W and delivers the substrate W to the plurality of pins 55b. The plurality of pins 55b support, from below, the substrate W horizontally above the bottom plate 55a. After delivering the substrate W to the plurality of pins 55b, the third transfer arm 53a retracts to the positive X-axis side of the delivery table 55.

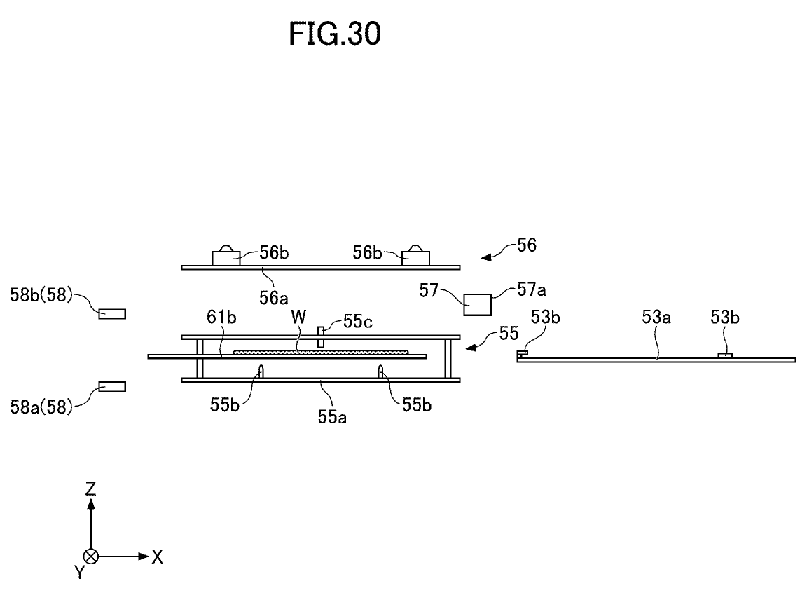

Next, as illustrated in FIG. 30, the fourth transfer arm 61b receives the substrate W supported by the plurality of pins 55b.

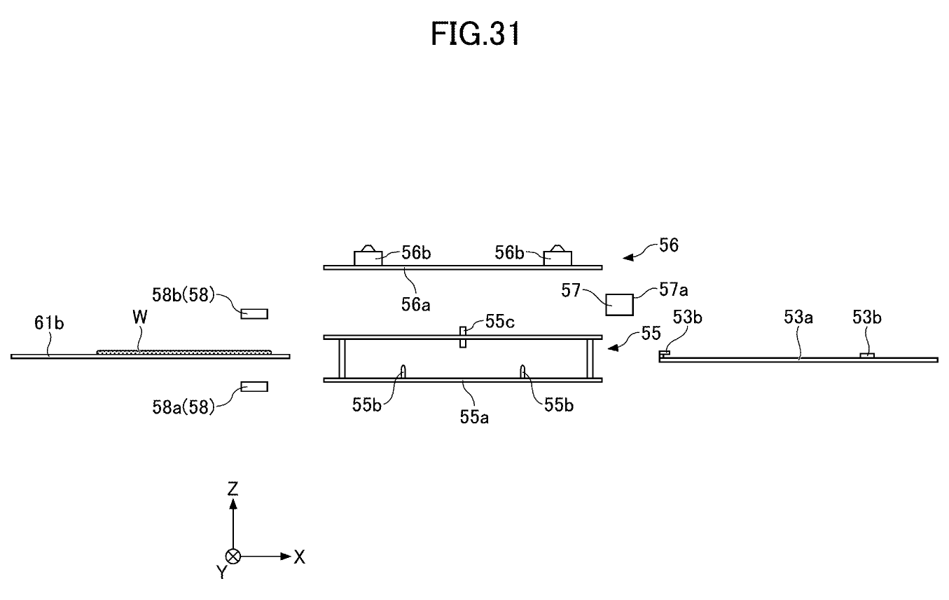

Next, as illustrated in FIG. 31, the fourth transfer arm 61b retracts to the negative X-axis side of the delivery table 55 while holding the substrate W. At this time, the detection section 58 detects the shift amount, in the horizontal direction, of the substrate W held by the fourth transfer arm 61b moving toward the negative side of the X-axis, and transmits the detected shift amount to the control circuit 9. The control circuit 9 corrects the third insertion position (horizontal position) of the third transfer arm 53a so that the received shift amount becomes 0 (zero). With this, the positional accuracy when the third transfer arm 53a mounts the next substrate W on the delivery table 55 is improved.

According to the other example of the method of adjusting the substrate transfer position described above, first, the shift amount of the substrate W with respect to the reference position is detected while the fourth transfer arm 61b holds the substrate W acquired from the delivery table 55. Then, based on the detected shift amount, the horizontal position when the third transfer arm 53a mounts the substrate W on the delivery table 55 is corrected. In this case, the shift of the substrate W transferred from the batch processing section 4 to the single-substrate processing section 6 can be reduced.

Here, in the examples described above, the case where the third insertion position of the third transfer arm 53a is corrected based on the shift amount of a single substrate W has been described, but the embodiment is not limited thereto. For example, the third insertion position of the third transfer arm 53a may be corrected based on an average value of shift amounts of a plurality of substrates W.

In the embodiment described above, the second interface section 5 is an example of a substrate standby section. The third transfer device 53 is an example of a first transfer robot, and the third transfer arm 53a is an example of a first holding section. The fourth transfer device 61 is an example of a second transfer robot, and the fourth transfer arm 61b is an example of a second holding section.

The embodiments disclosed herein should be considered exemplary in all respects and not restrictive. The embodiments described above may be omitted, replaced, or modified in various ways without departing from the scope and intent of the appended claims.

According to the present disclosure, a shift of a substrate transferred from a batch processing section to a single-substrate processing section can be reduced.

What is claimed is:

1. A method of adjusting a substrate transfer position in a substrate processing system including: a batch processing section configured to collectively process a plurality of substrates; a single-substrate processing section configured to process the plurality of substrates one by one; and a substrate standby section configured to cause a substrate to be transferred from the batch processing section to the single-substrate processing section to wait, the substrate standby section including: a delivery table on which the substrate is to be mounted; and a first transfer robot configured to mount, on the delivery table, the substrate processed by the batch processing section, the single-substrate processing section including a second transfer robot configured to acquire the substrate from the delivery table, the first transfer robot including a first holding section configured to hold the substrate, and the second transfer robot including a second holding section configured to hold the substrate, the method comprising:
acquiring, by the second holding section, the substrate from the delivery table;
detecting a shift amount of the substrate with respect to a reference position while the second holding section holds the substrate acquired from the delivery table; and
correcting a horizontal position when the first holding section mounts the substrate on the delivery table, based on the detected shift amount.

2. The method of adjusting the substrate transfer position as claimed in claim 1,
wherein the substrate is a dummy substrate, and
wherein the method of adjusting the substrate transfer position is performed by using the dummy substrate before processing on a product substrate is performed.

3. The method of adjusting the substrate transfer position as claimed in claim 1,
wherein the substrate is a product substrate, and
wherein the method of adjusting the substrate transfer position is performed by using the product substrate when processing on the product substrate is performed.

4. The method of adjusting the substrate transfer position as claimed in claim 1, wherein the first transfer robot is a six-axis vertically articulated robot.

5. The method of adjusting the substrate transfer position as claimed in claim 1, wherein the shift amount is a horizontal shift amount.

6. The method of adjusting the substrate transfer position as claimed in claim 1, wherein the shift amount is detected when the second holding section is moving.

7. The method of adjusting the substrate transfer position as claimed in claim 1, wherein the shift amount is detected by a detection section including a light projection section and a light reception section facing each other across a path through which the substrate passes when the second holding section transfers the substrate acquired from the delivery table.

8. A substrate transfer method in a substrate processing system including: a batch processing section configured to collectively process a plurality of substrates; a single-substrate processing section configured to process the plurality of substrates one by one; and a substrate standby section configured to cause a substrate to be transferred from the batch processing section to the single-substrate processing section to wait, the substrate standby section including: a delivery table on which the substrate is to be mounted; and a first transfer robot configured to mount, on the delivery table, the substrate processed by the batch processing section, the single-substrate processing section including a second transfer robot configured to acquire the substrate from the delivery table, the first transfer robot including a first holding section configured to hold the substrate, and the second transfer robot including a second holding section configured to hold the substrate, the substrate transfer method comprising:
acquiring, by the second holding section, the substrate from the delivery table;
detecting a shift amount of the substrate with respect to a reference position while the second holding section holds the substrate acquired from the delivery table; and
correcting a horizontal position when the first holding section mounts the substrate on the delivery table, based on the detected shift amount.

9. A substrate processing system comprising:
a batch processing section configured to collectively process a plurality of substrates;
a single-substrate processing section configured to process the plurality of substrates one by one;
a substrate standby section configured to cause a substrate to be transferred from the batch processing section to the single-substrate processing section to wait; and
a control circuit,
wherein the substrate standby section includes:
a delivery table on which the substrate is to be mounted; and
a first transfer robot configured to mount, on the delivery table, the substrate processed by the batch processing section, the single-substrate processing section including a second transfer robot configured to acquire the substrate from the delivery table, the first transfer robot including a first holding section configured to hold the substrate, and the second transfer robot including a second holding section configured to hold the substrate, and
wherein the control circuit is configured to:
acquire, by the second holding section, the substrate from the delivery table;
detect a shift amount of the substrate with respect to a reference position while the second holding section holds the substrate acquired from the delivery table; and
correct a horizontal position when the first holding section mounts the substrate on the delivery table, based on the detected shift amount.
